(19) United States
(12) Patent Application Publication
(10) Pub. No.: US 2024/0333258 A1
(43) Pub. Date: Oct. 3, 2024

(54) FILTER DEVICE WITH PCB HEAT SPREADER AND INTEGRATED GROUND INDUCTANCE

(71) Applicant: Murata Manufacturing Co., Ltd., Nagaokakyo-shi (JP)

(72) Inventors: Luke MYERS, Santa Barbara, CA (US); Wei YANG, Goleta, CA (US); Greg DYER, Santa Barbara, CA (US)

(21) Appl. No.: 18/616,039

(22) Filed: Mar. 25, 2024

Related U.S. Application Data
(60) Provisional application No. 63/493,167, filed on Mar. 30, 2023.

(51) Int. Cl. H03H 9/56; H03H 9/02; H05K 1/02; H05K 1/16

(52) U.S. Cl. CPC H03H 9/568; H03H 9/02228; H05K 1/0233; H05K 1/165; H05K 2201/10098

(57) ABSTRACT

A filter is provided that a piezoelectric layer, an interdigital transducers (IDT) having interleaved fingers at the piezoelectric layer, contact pads at the piezoelectric layer and electrically coupled to the IDT, and a printed circuit board (PCB). The PCB includes a plurality of layers including at least one layer that includes a first portion and a second portion that is physically separate from the first portion with a gap therebetween. Moreover, a plurality of electrical contacts are provided on a top layer of the plurality of layers that is facing the piezoelectric layer, with the plurality of electrical contacts electrically coupled to the plurality of contact pads, respectively.

### CROSS REFERENCE TO RELATED APPLICATIONS

This application claims priority to U.S. Patent Provisional Application No. 63/493,167, filed Mar. 30, 2023, the entire contents of which are hereby incorporated by reference.

### TECHNICAL FIELD

This disclosure relates to radio frequency filters using acoustic wave resonators, and, more, specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially and/or predominantly attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band may depend on the specific application. For example, in some cases a “pass-band” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

Thus, according to an exemplary aspect, a filter device is provided that includes a piezoelectric layer; an interdigital transducer (IDT) having interleaved fingers at the piezoelectric layer; a plurality of contact pads at the piezoelectric layer and electrically coupled to the IDT; and a printed circuit board (PCB) comprising a plurality of layers comprising at least one layer that includes a first portion and a second portion that is physically separate from the first portion with a gap therebetween; and a plurality of electrical contacts on a top layer of the plurality of layers that is facing the piezoelectric layer, with the plurality of electrical contacts electrically coupled to the plurality of contact pads, respectively.

In another exemplary aspect of the filter device, each of the plurality of layers comprises a planar shape and the gap between the first portion and the second portion of the at least one layer configures a band-rejection of the filter device.

In another exemplary aspect of the filter device, the plurality of layers of the PCB are stacked and electrically connected by vias on each respective layer of the plurality of layers to form an embedded inductor in the PCB.

In another exemplary aspect of the filter device, at least a portion the vias on the at least one layer of the plurality of layers are offset relative to a stacking direction from at least a portion of the vias on an adjacent layer of the plurality of layers.

In another exemplary aspect of the filter device, the plurality of layers are four metal layers.

In another exemplary aspect of the filter device, the at least one layer comprises a planar shape with the first portion and the second portion being in a same plane and that is physically separated from each other by the gap.

In another exemplary aspect, the filter device further includes a substrate; and at least one intermediate layer having a cavity disposed therein. In this aspect, the IDT is disposed at least on a portion of the piezoelectric layer that is over the cavity in the at least one intermediate layer. Moreover, the IDT can be on a surface of the piezoelectric layer that faces the cavity.

In another exemplary aspect of the filter device, the piezoelectric layer and the IDT are configured such that a respective radio frequency signal applied to the IDT primarily excites a shear acoustic mode within the respective piezoelectric layer and that propagates in a direction substantially orthogonal to a surface of the piezoelectric layer.

In another exemplary aspect of the filter device, the plurality of contact pads are coupled to the plurality of electrical contacts via one or more metal layers.

In another exemplary aspect of the filter device, the at least one layer is a second layer of the plurality of layers that is directly coupled to the top layer of the plurality of layers.

In another exemplary aspect, a radio frequency module is provided that includes a radio frequency circuit; and a filter device coupled to the radio frequency circuit, the filter device and the radio frequency circuit being enclosed within a common package. In this aspect, the filter device comprises at least one bulk acoustic resonator comprising a piezoelectric layer and an interdigital transducer (IDT) having interleaved fingers at the piezoelectric layer, a plurality of contact pads at the piezoelectric layer and electrically coupled to the IDT, and a printed circuit board (PCB) comprising a plurality of layers and a plurality of electrical contacts on a top layer of the plurality of layers that is facing the piezoelectric layer, with the plurality of electrical contacts electrically coupled to the plurality of contact pads, respectively. Moreover, the plurality of layers includes at least one layer having a first portion and a second portion that is physically separate from the first portion with a gap therebetween.

In another exemplary aspect, a printed circuit board (PCB) is provided that includes a plurality of layers comprising at least one layer that includes a first portion and a second portion that is physically separate from the first portion with a gap therebetween; and a plurality of electrical contacts on an outer layer of the plurality of layers. Moreover, in an exemplary aspect, each of the plurality of layers comprise a planar shape and the gap between the first portion and the second portion of the at least one layer configures a band-rejection of a filter device coupled thereto. The plurality of layers are stacked and electrically connected by vias on each respective layer of the plurality of layers to form an embedded inductor in the PCB. Yet further, at least a portion the vias on the at least one layer of the plurality of layers are offset relative to a stacking direction from at least a portion of the vias on an adjacent layer of the plurality of layers. The at least one layer can comprise a planar shape with the first portion and the second portion being in a same plane and that is physically separated from each other by the gap.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplarily pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6A is a schematic cross-sectional view of a packaged filter device according to an exemplary aspect.

FIG. 6B is a schematic cross-sectional view of a packaged filter device according to another exemplary aspect.

FIGS. 7A and 7B are schematic cross-sectional views packaged filter devices according to other exemplary aspects.

FIG. 8 is a schematic cross-sectional view of a packaged filter device according to another exemplary aspect.

FIG. 9 is a schematic cross-sectional view of a packaged filter device according to another exemplary aspect.

FIG. 10 is a schematic exploded plan view of a PCB in accordance with an exemplary aspect of the disclosure.

FIG. 11 is a schematic exploded plan view of a PCB in accordance with another exemplary aspect of the disclosure.

FIG. 12 is a schematic plan view of a packaged XBAR filter including a PCB for an RF and thermal circuit.

FIG. 13 illustrates a comparison between a PCB having continuous layers and a PCB of an exemplary aspect having a layer with two separate and discrete portions.

FIG. 14 illustrates a heat map of layer of a PCB having continuous sheet design.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously described element having the same reference designator.

### DETAILED DESCRIPTION

A transversely-excited film bulk acoustic resonator (XBAR) is a resonator structure for use in microwave filters. As described in detail below, an XBAR device includes an IDT formed at or on a piezoelectric material or layer (e.g., a plate). A microwave signal applied to the IDT excites a shear primary acoustic wave in the piezoelectric diaphragm, such that the acoustic energy flows substantially and/or predominantly normal to the surfaces of the layer, which is orthogonal or transverse to the direction of the electric field generated by the IDT. XBAR resonators provide very high electromechanical coupling and high frequency capability.

After fabrication of an XBAR device, it can be mounted to a printed circuit board (“PCB”) and then included as part of a radio frequency module configured to be used in a radio frequency (“RF”) communication device (e.g., a wireless phone or smartphone). To improve RF performance, the exemplary aspects of the PCB can use embedded inductance. However, embedding inductors in a PCB will also degrade the PCB by introducing long traces with high thermal impedances. Accordingly, the exemplary aspects provide for a filter device that includes one or more XBAR devices and simultaneously uses embedded inductances in the PCB in parallel with an effect heat spreading circuit. That is, the exemplary aspects implement a configuration that retains the embedded inductors without compromising the PCB's thermal performance in order to co-optimize both the RF and thermal performance of an acoustic filter. Exemplary aspects are provided as follows.

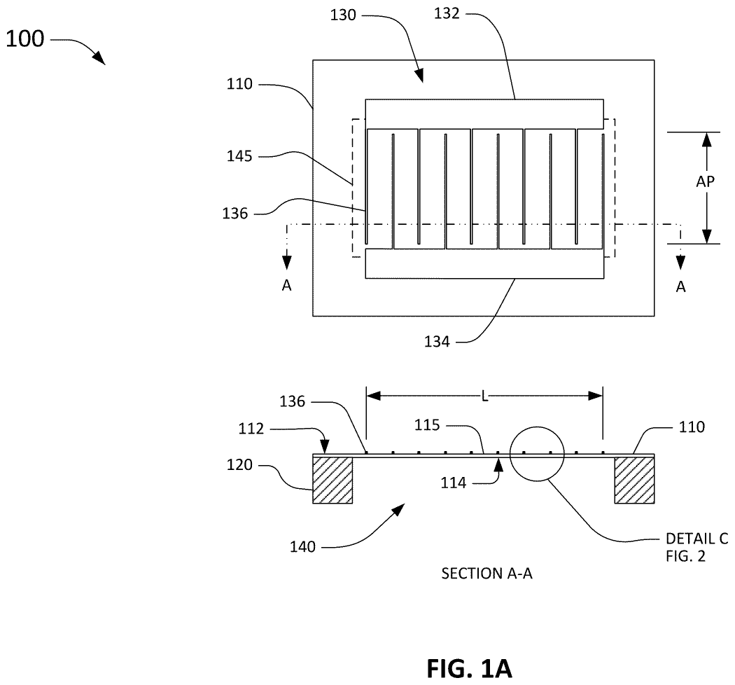

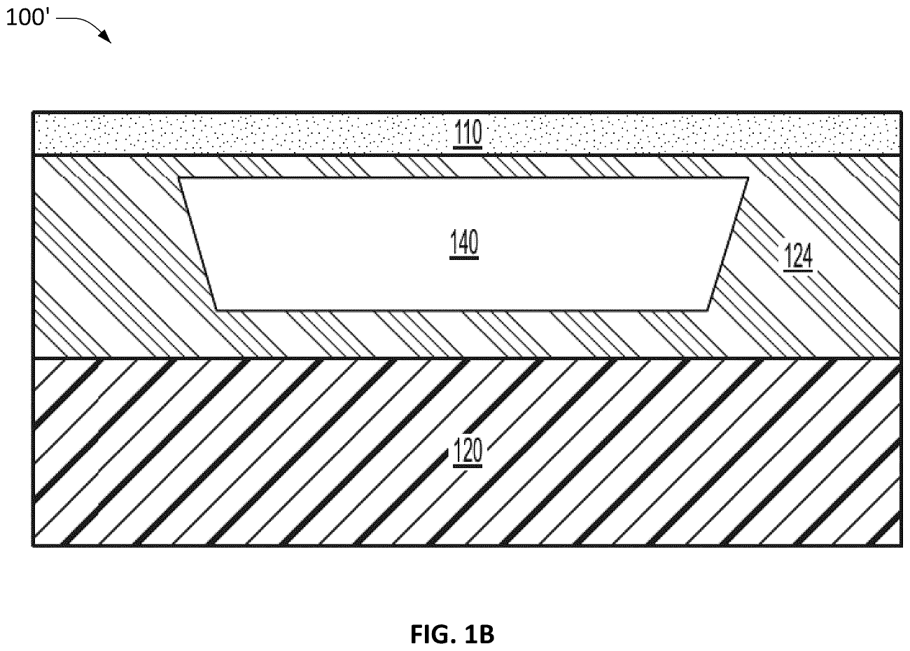

First, FIG. 1A shows a simplified schematic top view and orthogonal cross-sectional views of a bulk acoustic resonator device, namely a transversely excited film bulk acoustic resonator (XBAR) 100. XBAR resonators, such as the resonator 100, may be used in a variety of RF filters including band-rejection filters, band-pass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel, or substantially and/or predominantly parallel, front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to 0+90°. For example, a layer with Euler angles [0°, 30°, 0° ] is commonly referred to as “1200 rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over in the thickness direction) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

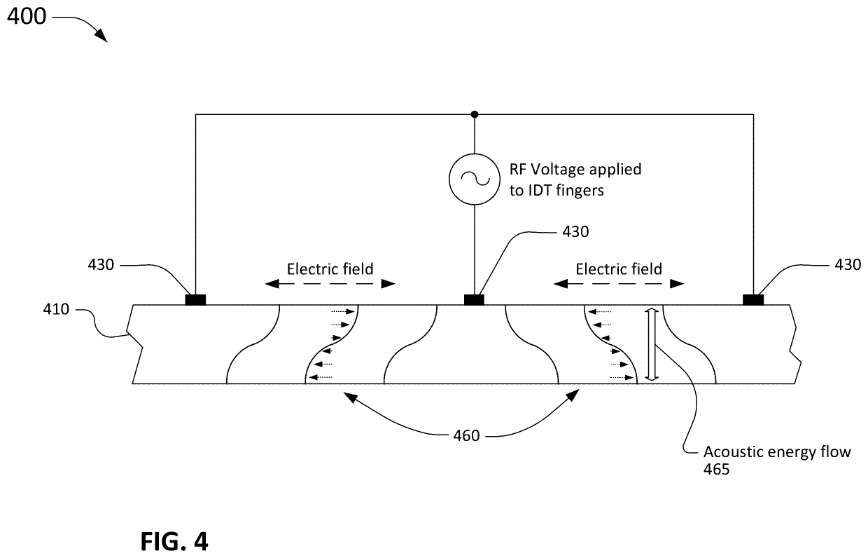

The first and second busbars 132, 134 are configured as the terminals of the XBAR 100. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

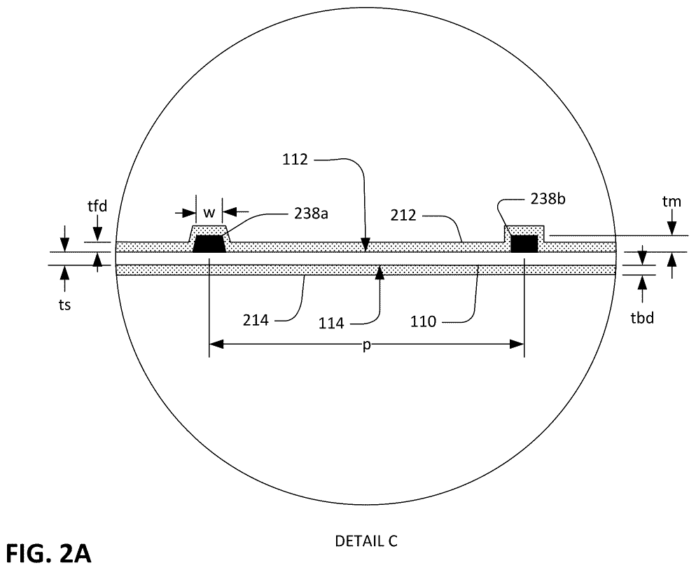

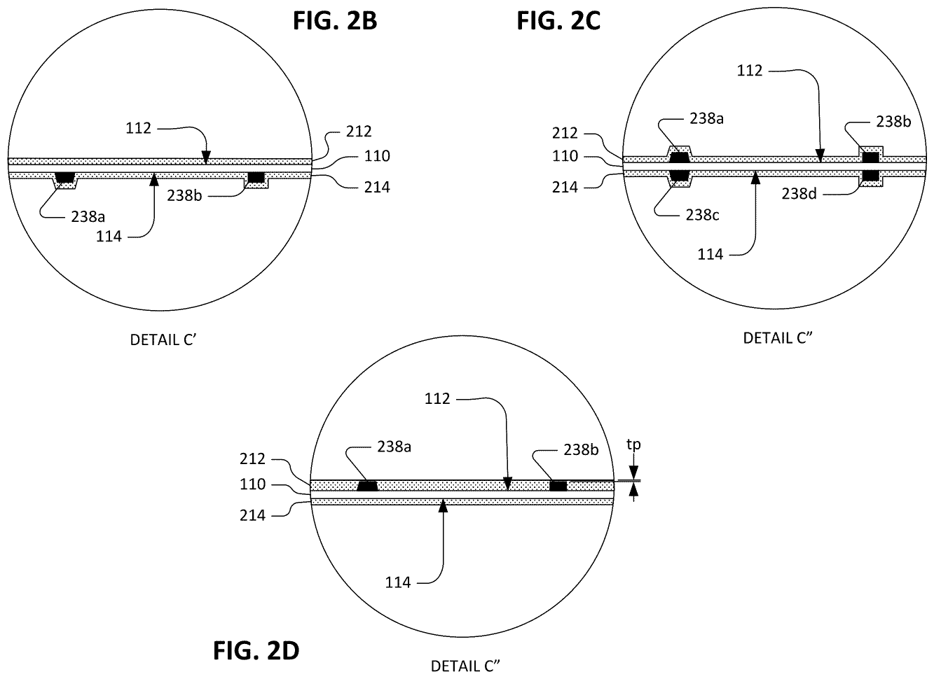

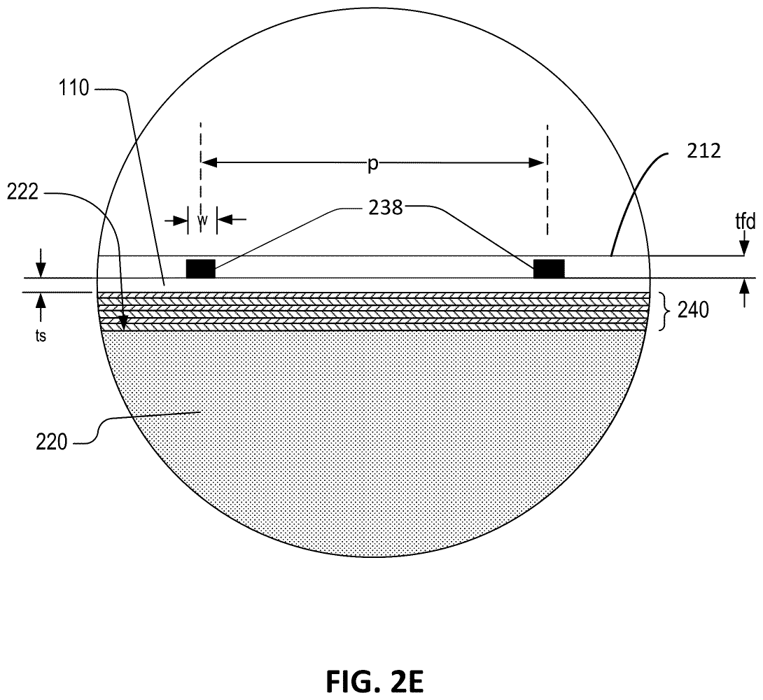

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHz, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate according to an exemplary aspect. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212 according to an exemplary aspect. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially and/or predominantly aluminum alloys, copper, substantially and/or predominantly copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects.

Dimension p (the “pitch”) is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a shear thickness mode, as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

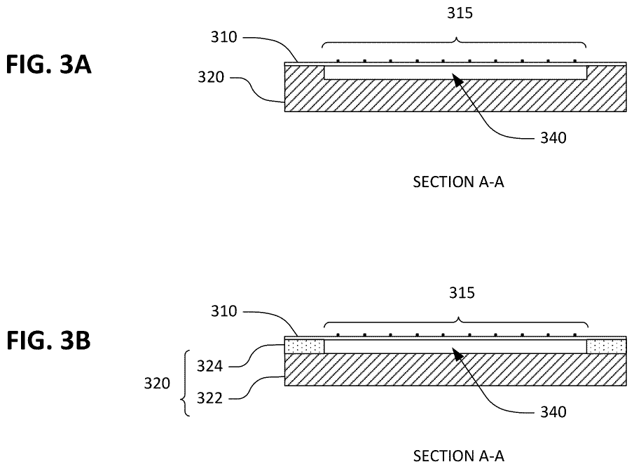

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

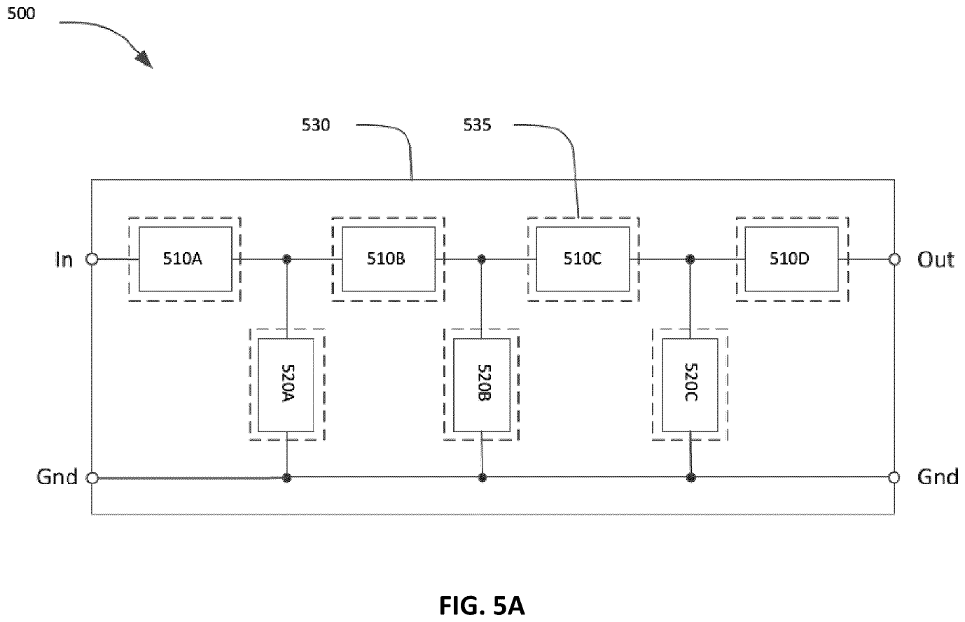

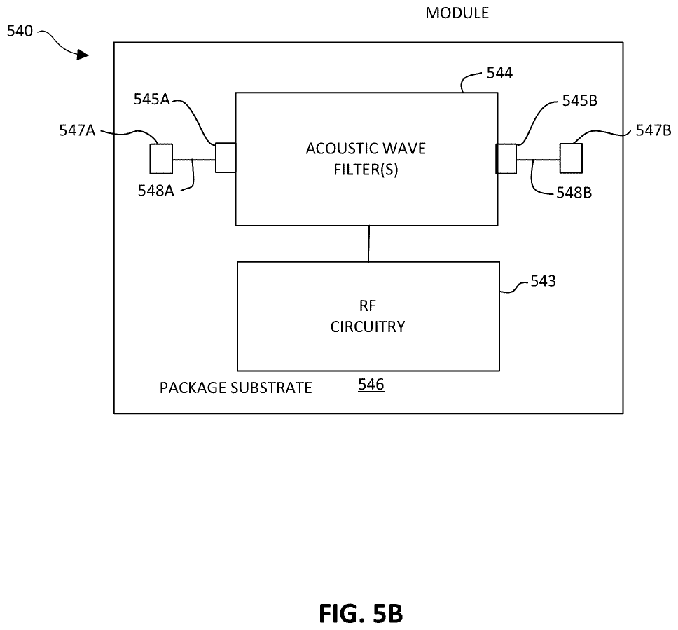

FIG. 5A is a schematic circuit diagram and layout for a high frequency band-pass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, having a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least three shunt resonators, such as the shunt resonators 520A-520C, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically for a split ladder and non-split-ladder filter architectures, all of the series resonators are connected in series between an input and an output of the filter and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate piezoelectric layer bonded to a separate substrate, for example. In some cases, this may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A-510D and the shunt resonators 520A-520C can have an XBAR configuration as described above with respect to FIGS. 1-2D in which a diaphragm with IDT fingers spans over a cavity. Alternatively, each of the series resonators 510A-510D and the shunt resonators 520A-520C can have an XBAR configuration in which the resonators can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

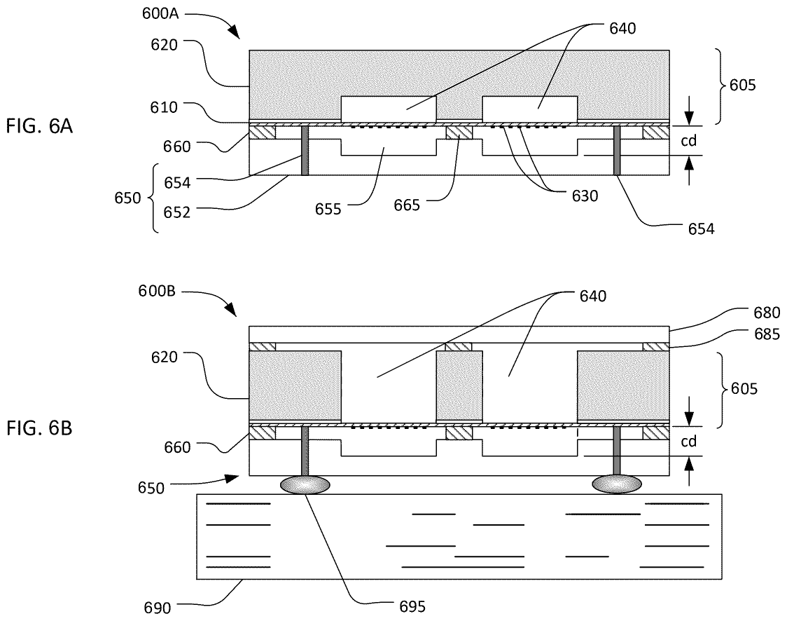

FIG. 6A and FIG. 6B are schematic cross-sectional views of packaged XBAR filter devices, each of which comprises an XBAR filter chip 605 and a PCB 650, which can be considered an interposer in an exemplary aspect. In general, it is noted that while the cross-sectional views of FIG. 6A and FIG. 6B show the XBAR filter chips 605 containing two XBARs, filters may commonly include five to nine XBARs. Specifically, FIG. 6A is a schematic cross-sectional view of a packaged filter 600A using front-side etched XBARs, and FIG. 6B is a schematic cross-section view of a packaged XBAR filter 600B using back-side etched XBARs. FIG. 6A and FIG. 6B are intended to illustrate the configurations for the package for an exemplary filter, but they do not necessarily represent practical package structures.

Referring to FIG. 6A, the XBAR filter chip 605 includes a piezoelectric layer 610 attached to a substrate 620. In general, the XBAR filter chip 605 can be implemented according to any of the configurations described above with respect to FIGS. 1-3. Thus, in an exemplary aspect, portions of the piezoelectric layer (which can be one or more piezoelectric layers) form diaphragms spanning respective cavities 640 in the substrate 620. Although not shown in FIG. 6A, the respective cavities 640 can alternatively be in the one or more intermediate or dielectric layer, such as cavity 140 in dielectric layer 124 as shown in FIG. 1B and described above. As also shown in FIG. 3Bm one or more intermediate layers (e.g., layer 324) can be disposed between the piezoelectric layer 610 and the substrate 620. Conductor patterns including IDTs are formed on the surface of the piezoelectric layer 610 such that interleaved IDT fingers, such as IDT fingers 630, are disposed on the respective diaphragms. As noted above, the XBAR structure can generally correspond to any of the structures described above with respect to FIG. 1 and FIGS. 2A to 2D, and, therefore, the IDT fingers can be on either (or both) surfaces of the piezoelectric layer. Moreover, the conductor pattern on the piezoelectric layer 610 can include a first plurality of contact pads facing the PCB 650.

The PCB 650 also includes a base 652 and conductive vias 654 to provide electrical connections between the conductor pattern(s) on the piezoelectric layer 610 and circuitry external to the filter (not shown). In an exemplary aspect, the PCB 650 can include a second plurality of contact pads disposed on a top layer of the PCB that is facing the at least one piezoelectric layer 610. It is noted that the top layer (e.g., layer L1) and the bottom layer (e.g., layer L4) of the PCB can be considered outer layers of the PCB as they are the external respective layers that oppose each other with one or more layers (including the divided layer, for example layer L2) disposed therebetween. Thus, in the exemplary aspect, the plurality of contact pads are disposed on the top layer of the PCB, which is the outer layer that faces the at least one piezoelectric layer 610. Moreover, the first plurality of contact pads can be electrically connected to the second plurality of contact pads either directly or by one of the conductive vias 654. It is noted that while the conductive vias 654 are shown to be linear and each extend in the thickness (or stacking) direction of the PCB 650, the PCB 650 can have a plurality of layers with vias on each layer that are offset from one another in the thickness direction as will be described in detail below.

As noted above, the PCB 620 can also be referred to as an interposer. For purposes of this disclosure, the term “interposer” is generally used to describe a passive circuit device that provides electrical connections between two different interfaces. The interposer (e.g., the PCB 650) fulfills this function, but it also forms a structural part of the package of the packaged XBAR filter 600A. According to the exemplary aspect, the interposer can be configured as PCB 650 and provides mechanical protection to the diaphragms of the XBARs.

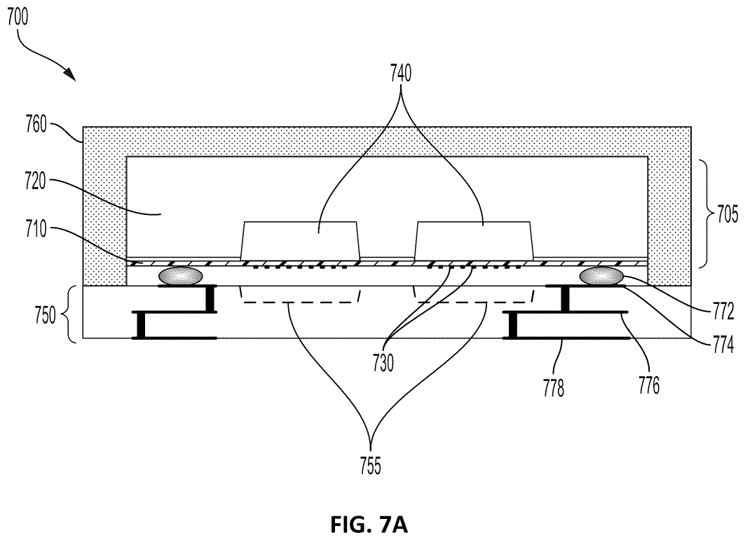

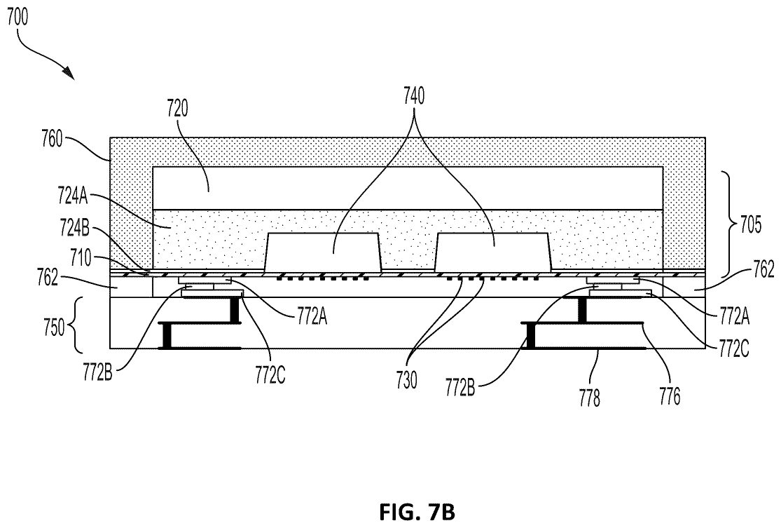

In FIG. 6A, the conductive vias 654 are illustrated schematically as simple pins extending though the base to the piezoelectric plate. Moreover, the PCB 650 can optionally include recesses 655 facing the diaphragms of the XBARs. Depending on the height of the seal mechanism 660 as described below, the PCB 650 can be disposed at a distance from the IDT fingers 630 that constricts the vibration mode of the piezoelectric layer 610 during operation. In these instances, recesses 655 may be provided to ensure sufficient spacing between the diaphragms (i.e., the portions of the piezoelectric layer 610) and the surfaces of the PCB 650 that faces these diaphragms (i.e., the bottom surfaces of the cavities 640). The required spacing (dimension cd in the FIG. 6A) depends on the material of the PCB and the recesses can be optionally be included to provide spacing for the vibration mode. In an alternative aspect, the PCB 650 does not include recesses 655 of which an example is described below in FIG. 7B.

Referring back to FIG. 6A, the PCB 650 is attached to the piezoelectric layer 610 by a seal 660. The seal 660 provides mechanical attachment and prevents intrusion of humidity and other fluids into the interior of the packaged XBAR filter 600A. As shown in FIG. 6A, the seal 660 is a distinct structure having a finite thickness that contributes to the total spacing cd between the diaphragms and the facing surfaces of the PCB 650. The seal 660 may be, for example, a thermocompression or ultrasonic bond between metal layers deposited on the piezoelectric plate and the PCB, a polymer or adhesive bond, a eutectic or solder bond, a glass frit bond, or some other bonding method and structure. Alternatively, the seal may be a bond, such as a plasma activated or surface activated wafer bond, directly between the PCB 650 and the piezoelectric layer 610. In this case (not shown in FIG. 6A), the thickness of the seal 660 may be negligible. In all cases, the seal 660 is present around the entire perimeter of the packaged XBAR filter 600A. In addition, the same sealing mechanism may attach the piezoelectric plate 610 to the PCB 650 at locations, such as location 665, in the interior of the packaged XBAR filter 600A.

Thus, according to the exemplary aspects, a filter device 600A is provided that includes a piezoelectric layer 610, an IDT 630 having interleaved fingers at the piezoelectric layer 610; and a plurality of contact pads at the piezoelectric layer 610 that are electrically coupled to the IDT 630. Moreover, the filter device 600A includes an PCB 650, i.e., a printed circuit board (PCB). As will be described in detail below, the PCB includes a plurality of layers including at least one layer that includes a first portion and a second portion that is physically separate from the first portion with a gap therebetween. Moreover; a plurality of electrical contacts are provided on a top layer of the plurality of layers that is facing the piezoelectric layer 610, such that the plurality of electrical contacts are electrically coupled to the plurality of contact pads, respectively.

FIG. 6B is a schematic cross-section view of a packaged XBAR filter 600B using back-side etched XBARs. Except for the depth of the cavities 640, the structure of the XBAR filter chip 605, the PCB 650, and the seal 660 between the PCB and the piezoelectric layer 610 are identical (or substantially similar) to the comparable elements in FIG. 6A. The descriptions of these elements will not be repeated.

In addition, the package XBAR filter 600B includes a cap 680 attached to the substrate 620 by a cap seal 685. The cap 680 may be any material suitable to cover the openings where the cavities 640 intersect the surface of the substrate 620. For example, the cap 680 may be silicon, glass, quartz, or a polymer plate or film. The cap seal 685 may be any of the materials and sealing methods previously described with respect to the seal 660.

FIG. 6B also illustrates the packaged XBAR filter 600B attached and electrically connected to a radio module circuit board 690 by a plurality of solder balls 695. This is an example of the use of the packaged filter device. The radio module circuit board 690 and the solder balls 695 are not part of the filter device 600B, but it can be included as part of the radio frequency module 540 as described above with respect to FIG. 5B.

FIG. 7A is a schematic cross-sectional view of another packaged XBAR filter 700 including an XBAR filter chip 705 with front-side etched cavities 740 and a printed circuit board (e.g., an interposer) 750. As in the previous examples, the XBAR filter chip 705 includes a piezoelectric layer 710 attached to a substrate 720. The substrate 720 may be high resistivity silicon or some other material. As also described above, portions of the piezoelectric layer 710 form diaphragms spanning respective cavities 740 in the substrate 720 (or alternatively in one or more intermediate layers disposed between the piezoelectric layer 710 and the substrate 720). That is, one or more intermediate layers can be disposed between the piezoelectric layer 710 and the substrate 720. A conductor pattern is formed on the surface of the piezoelectric layer 710. The conductor pattern includes IDTs with interleaved IDT fingers, such as fingers 730, disposed on the diaphragms.

The PCB 750 comprises a plurality of layers, some or all of which bear printed conductors, which are assembled and then fired to form a rigid multilayer circuit board. In the example of FIG. 7A, the PCB 750 has three conductor layers 774, 776, 778. In an exemplary aspect, the PCB can be configured as an LTCC interposer for an XBAR filter that may have more than three layers, as described below with reference to four metal layers. The availability of multiple conductor layers allows incorporation of passive components, such as inductors (e.g., embedded inductors), into the PCB 750. As described below, physically splitting one or more layers of the PCB 750 into first and second portions that are physically separated by a gap enables the PCB 750 to include embedded inductors with long traces while at the same time minimizing the compromise of the thermal performance of the PCB 750.

Moreover, in an exemplary aspect, the PCB 750 may have recesses 755 to ensure sufficient spacing between the diaphragms and the surfaces of the PCB facing the diaphragms. Such recess may be formed, for example, by punching openings in one or more of the ceramic layers prior to cofiring the layers of the PCB.

The XBAR filter chip 705 is flip-chip mounted to the PCB 750 and a polymer cover 760 can be provided as a molding over the assembly to provide a near-hermetic seal. Moreover, the flip-chip mounting establishes physical and electric connections between the XBAR filter chip 705 and the PCB 750. As shown in FIG. 7A, the connections are made by a plurality of solder balls such as solder ball 772. Alternatively, the connections made be made by thermocompression or ultrasonic bonding of gold bumps or layers on the XBAR filter chip 705 and the PCB 750, which is shown in FIG. 7B as follows.

In particular, FIG. 7B is a schematic cross-sectional view of a refinement of the packaged XBAR filter 700 including an XBAR filter chip 705 with cavities 740 and a printed circuit board (e.g., an interposer) 750. In this aspect, the XBAR filter chip 705 comprises similar configuration as described above with respect to FIGS. 2B and 3B in which one or more dielectric layers 724A and 724B are disposed on substrate 720 and coupled the piezoelectric layer 710 to the substrate 720. In this example, the cavities of the XBAR filter chip 705 are disposed in the one or more dielectric layers 724A and 724B. In one aspect, the cavities 740 may be in both dielectric layers 724A and 724B in a similar configuration as shown in FIG. 3B. In an alternative aspect, the cavity may only be in dielectric layer 724A and dielectric layer 724B may extend across the surface of the piezoelectric layer 710 in a similar configuration as shown in FIG. 1B.

In either aspect, there are no recesses in the PCB 750, which is coupled to the piezoelectric layer 710 by a plurality of metal layers (e.g., gold layers) 772A, 772B and 772C that may have varying widths as illustrated in the exemplary aspect. It is noted that while three metal layers tare shown for the connection, there can be two or four or more layers in alternative aspects. In an exemplary aspect as described below, at least one of the metal layers (e.g., layer 772C) can be configured as one or a plurality of electrical contacts on a top layer of the PCB 750 that faces the piezoelectric layer.

These metal layers 772A, 772B and 772C are general shown to be outside the IDTs 730 in the widthwise direction of the resonators. In addition, the PCB 750 in this exemplary aspect does not have any recesses (e.g., recesses 755 of FIG. 7A) and is coupled to the perimeter of the piezoelectric layer 710 by a metal seal or ring 762 (which can also be a stacked plurality of metal layers) as described herein, similar to the seal 660 as discussed above. For purposes of this disclosure, it is noted that the term “perimeter” means at or near the outer edges of the respective layers in a widthwise direction thereof. However, it should generally be appreciated that the seal or ring 762 only needs to encapsulate the IDTs 730 to protect the resonators and provide mechanical support. The seal or ring will typically not be electrically coupled to the conductor patterns forming the IDT 730 and/or metal layers 772A, 772B and 772C according to the exemplary aspect.

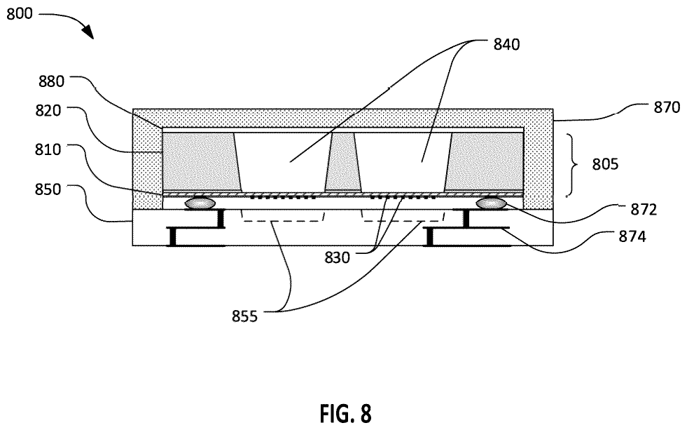

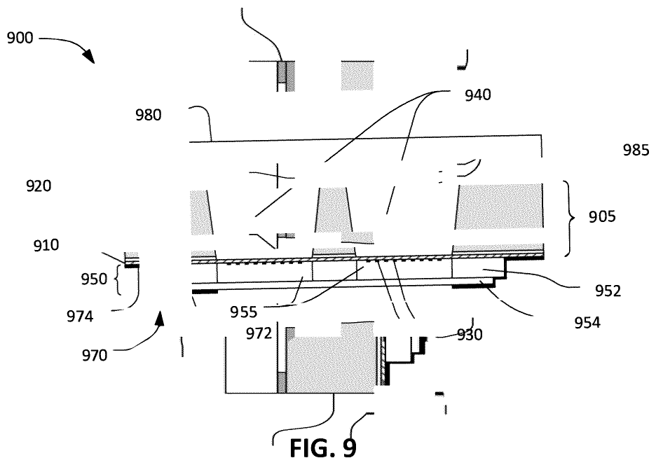

FIG. 8 is a schematic cross-sectional view of another packaged XBAR filter 800 including an XBAR filter chip 805 with back-side etched cavities and a PCB 850. As in the previous examples, the XBAR filter chip 805 includes a piezoelectric layer 810 attached to a substrate 820 either directly or via one or more intermediate layers. With the exception of a cap 880, the identified elements in FIG. 8 have the structure and function as the corresponding elements of FIG. 7. For example, recesses 855 can correspond to recesses 755, layer 874 can correspond to one or more of layers 774, 776 and/or 778, fingers 830 can correspond to fingers 730, and solder ball 872 can correspond to solder ball 772. Descriptions of these elements will not be repeated.

In this example, the cap 880 is sealed to the substrate 820. Since the cap 880 is eventually enclosed by the molded cover 870, the primary function of the cap 880 is to prevent intrusion of materials, including the molding compound used for the cover 870, into the cavities 840. This function may be satisfied by a very thin cap, such as a plastic film.

FIG. 9 is a schematic cross-sectional view of yet another packaged XBAR filter 900 including an XBAR filter chip 905 with back-side etched cavities and a PCB 950 formed by layers built up on the surface of the XBAR filter chip. The XBAR filter chip 905 is a portion of a wafer (not shown) containing multiple XBAR filter chips. The build-up of the PCB layers is done on all of the XBAR filter chips simultaneously. Individual packaged XBAR filters are then excised from the wafer.

As in previous examples, the XBAR filter chip 905 includes a piezoelectric layer 910 attached to a substrate 920 either directly or via one or more intermediate layers. The substrate 920 may be high resistivity silicon or some other material. Portions of the piezoelectric layer 910 form diaphragms spanning respective cavities 940 in the substrate 920 or alternatively in the one or more intermediate layers. That is, one or more intermediate layers can be disposed between the piezoelectric layer 910 and the substrate 920. A conductor pattern is formed on the surface of the piezoelectric layer 910. The conductor pattern includes IDTs with interleaved IDT fingers, such as fingers 930, disposed on the diaphragms. A cap 980 is sealed to the substrate 920 by a cap seal 985 as previously described.

The PCB 950 includes at least three layers sequentially formed on the piezoelectric layer 910. The PCB (i.e., the interposer) for an XBAR filter may have more than three layers, as described below with reference to four metal layers. The availability of multiple conductor layers allows incorporation of passive components, such as embedded inductors, into the PCB 950.

As further shown, walls 952 surround the diaphragms of the XBAR devices. The thickness of the walls 952 defines the distance between the diaphragms and a cover layer 954 that spans the walls creating an enclosed cavity 955 over each diaphragm. Both the walls 952 and the cover layer 954 may be polymer materials. An PCB conductor pattern 970 includes contact pads 972 on the external surface of the cover layer 954 for connection to circuitry external to the packaged XBAR filter. In one aspect of the disclosure, the contact pads 972 are incorporated into the top layer (e.g., the layer directly facing the XBAR) of the PCB 950. The conductor pattern 970 connects the contact pads 972 to connection points 974 on the XBAR filter chip 905. The conductor pattern 970 may be aluminum, copper, gold, or a combination of materials.

According to an exemplary aspect, the plurality of contact pads 972 can generally be configured as a plurality of electrical contacts (e.g., land electrodes) that are on a top layer of the plurality of layers of the PCB 950 that is facing the piezoelectric layer 910. Moreover, the plurality of electrical contacts can be electrically coupled to the plurality of contact pads, respectively, on the piezoelectric layer 910. In an exemplary aspect, the plurality of contact pads can be coupled to the plurality of electrical contacts via one or more metal layers.

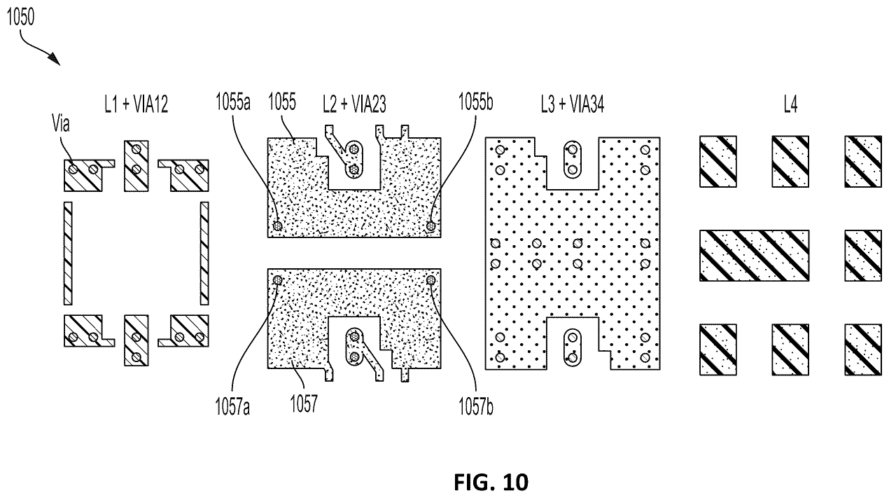

FIG. 10 is a schematic exploded plan view of a PCB (i.e., an interposer) in accordance with an exemplary aspect of the disclosure. As noted above, the terms interposer and PCB are used interchangeably for purposes of this disclosure. In general, PCB 1050 can correspond to any one of PCBs 650, 750, 850 and 950 as described above. In the exemplary aspect, PCB 1050 includes a plurality of layers, which are shown as four metal layers, L1, L2, L3 and L4. When constructed, the four metal layers are stacked on top of each other with L1 being the first or top layer. That is, layer L1 774 is the first or top layer that is coupled to the piezoelectric layer 710 by electrical contacts as described above. Moreover, layer L4 is the fourth or bottom layer that can be coupled, for example, to the radio module circuit board 690 as also described above. The layers L1, L2, L3 and L4 are stacked in a thickness (or vertical or stacking direction) and interconnected with a plurality of vias disposed on at least layers L1, L2 and L3. FIG. 10 illustrates that one via is marked, yet all circular areas are to each be considered a via conductor. In general, a via is an electrical/conductive connection between layers (e.g., copper layers) in a printed circuit board. Essentially, a via is a small, drilled hole that goes through two or more adjacent layers and where the hole is plated with copper (or some other conductive metal) that forms the electrical connection through the insulation that separates the copper layers. The metal layers of the of the PCB can thereby be configured as traces to provide an embedded inductor(s) in the PCB. Moreover the positioning of the vias can be adjusted to tune the inductance as will be described in more detail below.

In the exemplary aspect of the disclosure, L2 is a split or divided layer that includes two separate and discrete portions of the L2 layer, i.e., a pair of physically separated layer portions 1055 and 1057, separated by a distance or a gap. As described below, the layer L2 as a split or divided layer facilitates the implementation of embedded inductors in the PCB 1050 while acting as a heat spreader. That is, the gap or space between the separated layer portions 1055 and 1057 facilitates the offset of the high thermal impedances that would otherwise occur from introducing long traces for the embedded inductors in the PCB 1050. As a result, the single gap in layer L2, while otherwise fully filling L2 with conductor, significantly improves head spreading as compared with utilizing narrow traces on L2 as discussed below in more detail. In addition, splitting the layer L2 allows for each separated portion to be at different electrical potentials allowing for different electrical paths at the respective vias in different separated portions. This configuration provides a phase difference between these different vias in different separated portions and allows for an additional degree of freedom to achieve improved radio frequency performance while still maximizing heat dissipation that may be dependent on increasing area of the layer L2, as described herein.

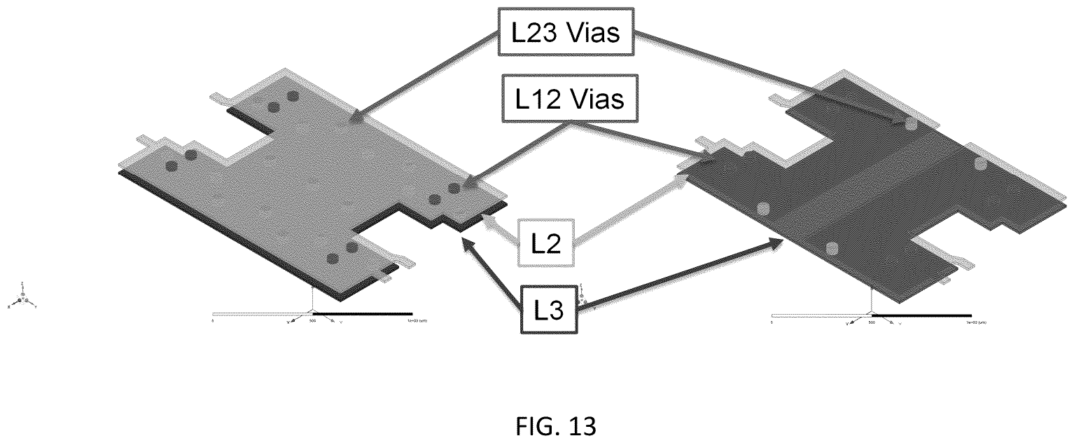

It is noted that other layers (e.g., layer L3) of the PCB 1050 can also have the split. Configuration. However, the second layer L2 of the plurality of layers that is directly coupled to the top layer L1 of the plurality of layers has the split configuration of the exemplary aspect. This configuration facilitates heat spreading (i.e., the heat generated from the acoustic filter during operation) and dissipating while the embedded inductance can be generated beneath layer L2 to improve the RF performance of the acoustic filter as described herein. Placing the split configuration on lower layers may result in a bottleneck of the heat and lower the dissipation effect of the exemplary aspect. That is, the thermal impedance will build up from one lower down to the next layer if the split configuration is in a lower layer of PCB 1050. Moreover and as discussed in more detail below, the rejection of the filter also increases (compared with a non-split configuration as shown in FIG. 13) when the ground is split in the configuration of layer L2 of the exemplary aspect.

As further shown, each portion of the layer L2, 1055 and 1057, include two vias 1055a and 1055b, 1057a and 1057b, respectively, located near or adjacent to a respective corner. The placement of the vias 1055a and 1055b, 1057a and 1057b primarily improves RF performance as also described below. Thus, in the exemplary aspect, the PCB 1050 comprises a plurality of layers (e.g., layers L1 to L4) that includes at least one layer (e.g., layer L2) that includes a first portion 1055 and a second portion 1057 that is physically separate from the first portion 1055 with a gap therebetween. As described herein, the gap between the first portion 1055 and the second portion 1057 of layer L2 configures a band-rejection of the filter device. Moreover, a plurality of electrical contacts can be formed on a top layer (e.g., layer L1) of the plurality of layers that is facing the piezoelectric layer (as shown above). These electrical contacts can be electrically coupled to the plurality of contact pads of the piezoelectric layer, respectively, as described above.

According to an exemplary aspect, each of the plurality of layers comprises a planar shape (e.g., in a width direction that is orthogonal to the thickness direction). These layers L1 to L4 of PCB 1050 are stacked and electrically connected by vias on each respective layer of the plurality of layers. Moreover, at least a portion the vias on the at least one layer (e.g., layer L2) are offset relative to a stacking direction from at least a portion of the vias on an adjacent layer (e.g., layer L3) of the plurality of layers. In other words, each layer L1-L3 can be a planar metal that extends in a two-dimensional (e.g., the X-Y axes) plane. The vias in each metal layer will typically extend in a direction orthogonal (e.g., the Z axis) to the planar surfaces of the respective layers. Accordingly, the vias extending in the Z axis in one layer (e.g., layer L2) will not be colinear with the vias layers extending in the Z axis in another layer (e.g., layer L3) when the layers are stacked on each other. Instead, they are offset relative to each other in this direction (i.e., the stacking or thickness direction) that is orthogonal to the planar surfaces of each respective layer. This configuration enables the PCB 1050 to form one or more embedded inductors with long traces to improve the band-rejection of the filter device.

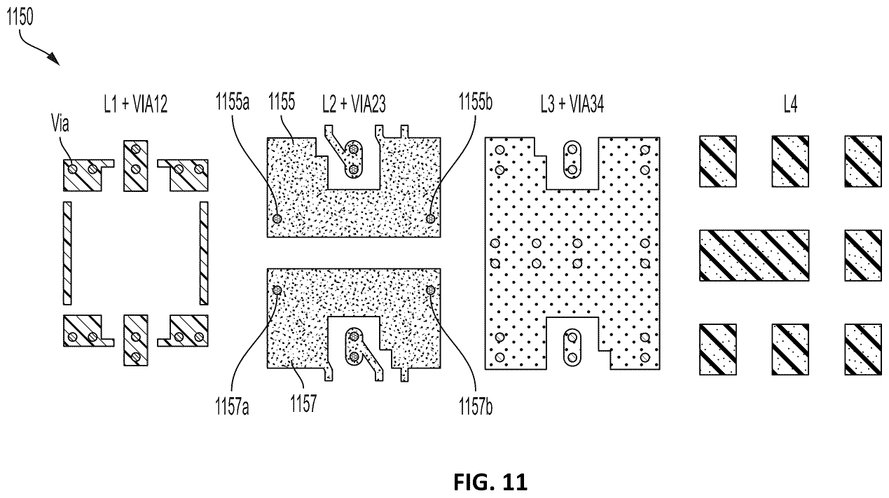

FIG. 11 is a schematic exploded a plan view of a PCB in accordance with an exemplar aspect of the present disclosure. As noted above, the terms interposer and PCB are used interchangeably for purposes of this disclosure. Moreover, PCB 1150 can correspond to any one of PCBs 650, 750, 850 and 950 and can include four metal layers, L1, L2, L3 and L4 in an exemplary aspect. However, in alternative aspects, the PCB 1150 may have less than or more than four metal layers as long as it includes split or divided layer (e.g., layer L2 as described above). In an exemplary aspect, each of the metal layers is a planar (or plate shaped) layer.

When constructed, the four metal layers are stacked on top of each other (i.e., in a thickness or stacking direction) with layer L1 being the first layer and L4 being the fourth layer. The layers L1, L2, L3 and L4 are interconnected with a plurality of vias. PCB 1150 has a similar configuration as PCB 1050 in that at least one of the layers (e.g., layer L2) is a split layer which includes two separate and discrete portions 1155 and 1157 of the layer L2. As shown, the split layer L2 can have a planar shape with the first portion 1155 and the second portion 1157 being in the same plane. The two discrete layer portions 1155 and 1157 are physically separate from each other with a gap (i.e., a defined space) therebetween that is configured for RF performance. Moreover, each portion of layer L2 include two vias 1155a and 1155b, 1157a and 1157b, respectively, located near or adjacent to a respective corner.

The placement of the vias 1155a and 1155b, 1157a and 1157b can be determined to configure both RF and thermal performance. Comparing the exemplary embodiments of FIG. 10 to FIG. 11, the vias 1155a, 1155b, 1157a and 1157b are shifted by 70 μm compared to vias 1055a, 1055b, 1057a and 1057b in order to tune inductance of the overall filter device and configure the frequency response. Thus, in an exemplary aspect, the vias in one or more of the layers may be offset or shifted with regard to the vias in the other layers. The placement of the vias can be determined based on the desired frequency response, which can be tuned by the inductance of the embedded inductor in the PCM. Thus, as shown, the plurality of layers of the PCB are stacked and electrically connected by the vias on each respective layer of the plurality of layers to configure the embedded inductor, which is formed by the vias in each layer and the respective traces. As also noted above, each of the vias in each layer can be offset from one another.

In general, it is noted that in both FIGS. 10 and 11, layer L1 includes vias 12 (“VIA12”), which denotes the vias connecting layer L1 to layer L2. Moreover, layer L2 includes vias 23 (“VIA23”), which denotes the vias connecting layer L2 to layer L3. Furthermore, layer L3 includes vias 34 (“VIA34”), which denotes the vias connecting layer L3 to layer L4. Finally, layer L4 can include a conductor pattern that electrically couples the overall PCB (e.g., PCB 1050 or PCB 1150) to a motherboard of the RF module as described above, for example.

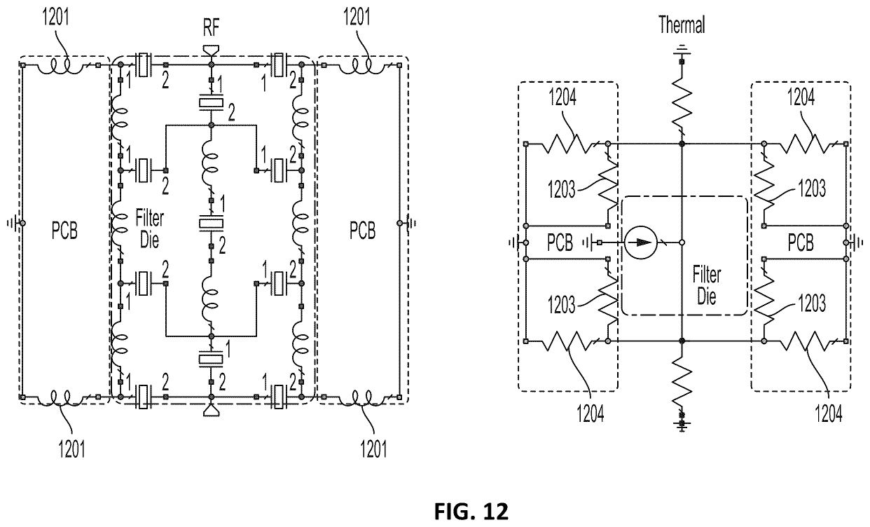

FIG. 12 illustrates a schematic plan view of a packaged filter device including a PCB for an RF and thermal circuit according to an exemplary aspect. As described above, each filter device can comprise a “filter die” having a plurality of acoustic resonators forming a ladder circuit, similar to the configuration described above with respect to FIG. 5A. Each resonator is shown between electrical connections “1” and “2”, which can represent the electrical potentials applied to each busbar, respectively. Moreover, the ladder circuit is coupled between two ports as also described above with respect to FIG. 5A.

In the exemplary schematic view, the electrical inductances are indicated as 1201 (which can be generated by the embedded inductor of the PCB as described above), the shunt thermal resistances are indicated as 1203, and the series thermal resistances are indicated as 1204. Th effect of heat spreading and heat conduction through the dielectric between metal layers in embodied by the shunt thermal resistance 1203. The series thermal resistance 1204 represents direct heat conduction on metal layers and in vias. Specifically, FIG. 12 illustrates the simultaneous use of embedded inductance in an RF circuit including a PCB, in parallel with an effect heat spreading thermal circuit. Though this process, the RF and thermal performance for an XBAR on a multi-chip module may be co-optimized. As noted above, embedded inductors in a PCB can degrade heat sinking through the PCB by introducing long traces with high thermal impedances. However, FIG. 12 illustrates a device that utilizes an embedded inductor(s) in the PCB without severely compromising the thermal performance (e.g., the thermal dissipation) of the PCB.

As described above with relation to FIG. 10 and FIG. 11, the inductances 1201 can be optimized by modifying the ground traces and the indicated via locations. Further, by overlapping the ground planes of layers L2 and L3, as described above in relation to FIG. 10 and FIG. 11, this configuration provides for a heat conduction channel through the PCB dielectric for the shunt resistances 1203. Additionally, a large area of layer L2 acts as a heat spreader, and thereby provides higher heat conduction in-plane, thus reducing thermal resistance in direct channels.

FIG. 13 illustrates a comparison between a continuous layer L2, i.e., absent a split region and configured as single layer design (e.g., design on the left), to the PCB having the exemplary layer L2 with a split configuration (e.g., design on the right), which includes two separate and discrete portions having their own separate electrical potential, according to the exemplary aspect. FIG. 13 illustrates the via configuration between layers L2 and L3 of each configuration. Although layer L2 as a single continuous layer has low RF capabilities, the layer L2 as a single continuous layer sheet design produces optimal thermal performance where heat is conducted though maximized L23 vias. In contrast, the exemplary configuration having layer L2 with the split design produces optimal RF capabilities (due to the embedded inductor with longer traces), as described above. Moreover, the layer L2 in the exemplary aspect produces good thermal performance where heat is conducted though layer L23 vias of the laminate layer, L3.

Table 1 as follows illustrates a comparison of the thermal resistance between the two configurations of FIG. 13.

TABLE 1

| | L2 Layer Single Sheet | L2 Layer Split Design |
|---|---|---|
| Thermal Resistance - | 50.7 C/W | 64.6 C/W |
| Nominal Model | | |
| Thermal Resistance - | 53.9 C/W | 106.6 C/W |
| No L2-L3 Laminate Heat | | |
| Conduction | | |

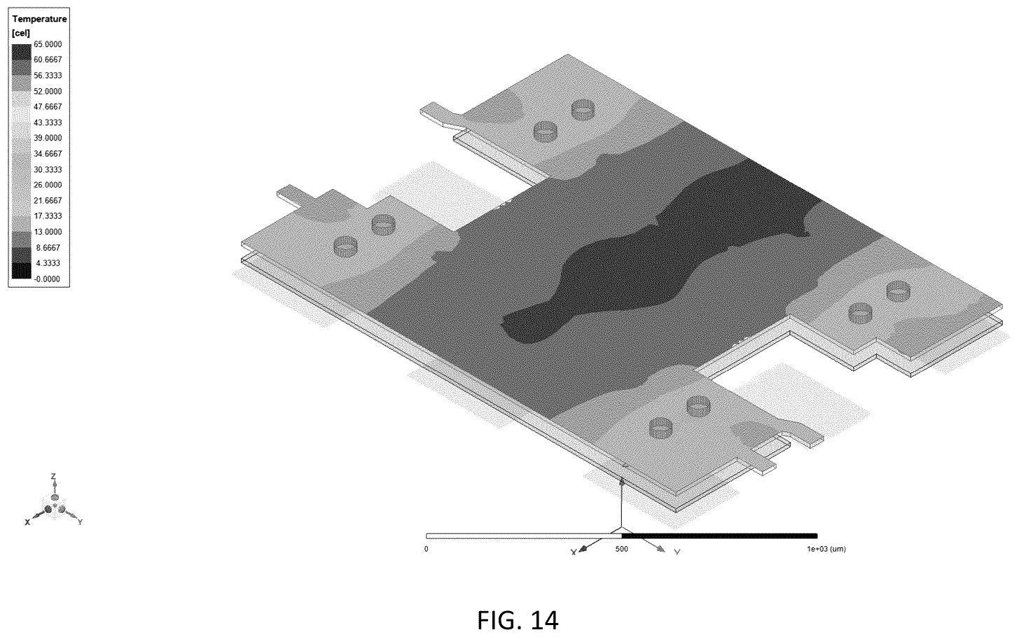

As indicated in Table 1, a finite element method (FEM) simulation of thermal resistance for the layer L2 (single sheet design) indicates little sensitivity of top heat flow through the laminate L3, due to high L23 via density. Moreover, the layer L2 (split design) has approximately a 27% increase in thermal resistance compared to the L2 layer single sheet design (i.e., without the split or divided configuration). FIG. 14 illustrates a heat map of layer L2 (single sheet design) from a simulation of the interposer thermal resistance, which illustrates the lower temperature in the middle portion of layer L2. This effect illustrates the technical effect leading to the approximately 27% increase in thermal resistance of the exemplary aspect. With that said, Table 1 further illustrates that disabling L2-L3 laminate heat conduction indicates L2-L3 conductor overlap mitigates this heat flow degradation. As a result, the layer L2 split design of the exemplary aspect has only a moderate cost/degradation with regards to thermal performance but provides for critical RF benefits compared with the single sheet configuration. Thus, Table 1 illustrates that the thermal resistance impact of the layer L2 split design approaches a 27% “cost” with a good L2-L3 layer overlap, though this degradation in heat conduction can be >100% when the L2-L3 conductor overlap is small.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/of” means that the listed items are alternatives, but the alternatives also include any combination of the listed items.

What is claimed:

1. A filter device comprising:
a piezoelectric layer;
an interdigital transducer (IDT) having interleaved fingers at the piezoelectric layer;
a plurality of contact pads at the piezoelectric layer and electrically coupled to the IDT; and
a printed circuit board (PCB) comprising:
a plurality of layers comprising at least one layer that includes a first portion and a second portion that is physically separate from the first portion with a gap therebetween; and
a plurality of electrical contacts on a top layer of the plurality of layers that is facing the piezoelectric layer, with the plurality of electrical contacts electrically coupled to the plurality of contact pads, respectively.

2. The filter device of claim 1, wherein each of the plurality of layers comprises a planar shape and the gap between the first portion and the second portion of the at least one layer configures a band-rejection of the filter device.

3. The filter device of claim 1, wherein the plurality of layers of the PCB are stacked and electrically connected by vias on each respective layer of the plurality of layers to form an embedded inductor in the PCB.

4. The filter device of claim 3, wherein at least a portion the vias on the at least one layer of the plurality of layers are offset relative to a stacking direction from at least a portion of the vias on an adjacent layer of the plurality of layers.

5. The filter device of claim 1, wherein the plurality of layers are four metal layers.

6. The filter device of claim 1, wherein the at least one layer comprises a planar shape with the first portion and the second portion being in a same plane and that is physically separated from each other by the gap.

7. The filter device of claim 1, further comprising:
a substrate; and
at least one intermediate layer having a cavity disposed therein,
wherein the IDT is disposed at least on a portion of the piezoelectric layer that is over the cavity in the at least one intermediate layer.

8. The filter device of claim 7, wherein the IDT is on a surface of the piezoelectric layer that faces the cavity.

9. The filter device of claim 7, wherein the piezoelectric layer and the IDT are configured such that a respective radio frequency signal applied to the IDT primarily excites a shear acoustic mode within the respective piezoelectric layer and that propagates in a direction substantially orthogonal to a surface of the piezoelectric layer.

10. The filter device of claim 1, wherein the plurality of contact pads are coupled to the plurality of electrical contacts via one or more metal layers.

11. The filter device of claim 1, wherein the at least one layer is a second layer of the plurality of layers that is directly coupled to the top layer of the plurality of layers.

12. A radio frequency module, comprising:
a radio frequency circuit;
a filter device coupled to the radio frequency circuit, the filter device and the radio frequency circuit being enclosed within a common package, wherein the filter device comprises:
at least one bulk acoustic resonator comprising a piezoelectric layer and an interdigital transducer (IDT) having interleaved fingers at the piezoelectric layer, a plurality of contact pads at the piezoelectric layer and electrically coupled to the IDT; and
a printed circuit board (PCB) comprising a plurality of layers and a plurality of electrical contacts on a top layer of the plurality of layers that is facing the piezoelectric layer, with the plurality of electrical contacts electrically coupled to the plurality of contact pads, respectively,
wherein the plurality of layers includes at least one layer having a first portion and a second portion that is physically separate from the first portion with a gap therebetween.

13. The radio frequency module of claim 12,
wherein the plurality of layers of the PCB are stacked and electrically connected by vias on each respective layer of the plurality of layers to form an embedded inductor in the PCB, and
wherein at least a portion the vias on the at least one layer of the plurality of layers are offset relative to a stacking direction from at least a portion of the vias on an adjacent layer of the plurality of layers.

14. The radio frequency module of claim 12, wherein each of the plurality of layers comprises a planar shape and the gap between the first portion and the second portion of the at least one layer configures a band-rejection of the filter device.

15. The radio frequency module of claim 12, wherein the at least one layer is a second layer of the plurality of layers that is directly coupled to the top layer of the plurality of layers.

16. A printed circuit board (PCB) comprising:
a plurality of layers comprising at least one layer that includes a first portion and a second portion that is physically separate from the first portion with a gap therebetween; and
a plurality of electrical contacts on an outer layer of the plurality of layers.

17. The PCB of claim 16, wherein each of the plurality of layers comprise a planar shape and the gap between the first portion and the second portion of the at least one layer configures a band-rejection of a filter device coupled thereto.

18. The PCB of claim 16, wherein the plurality of layers are stacked and electrically connected by vias on each respective layer of the plurality of layers to form an embedded inductor in the PCB.

19. The PCB of claim 18, wherein at least a portion the vias on the at least one layer of the plurality of layers are offset relative to a stacking direction from at least a portion of the vias on an adjacent layer of the plurality of layers.

20. The PCB of claim 16, wherein the at least one layer comprises a planar shape with the first portion and the second portion being in a same plane and that is physically separated from each other by the gap.
